(19) United States
(12) Patent Application Publication
(10) Pub. No.: US 2026/0150473 A1
(43) Pub. Date: May 28, 2026

(54) DISPLAY DEVICE

(71) Applicant: LG Display Co., Ltd., Seoul (KR)

(72) Inventors: Sumin Lee, Seoul (KR); Hun Jang, Paju-si (KR); ByungHyun Lee, Paju-si (KR)

(73) Assignee: LG Display Co., Ltd., Seoul (KR)

(21) Appl. No.: 19/307,825

(22) Filed: Aug. 22, 2025

(30) Foreign Application Priority Data
Nov. 27, 2024 (KR) 10-2024-0171941

(51) Int. Cl. H10H 29/855; G02F 1/1676; G02F 1/1677; H10H 29/85

(52) U.S. Cl. CPC H10H 29/8552; G02F 1/1676; G02F 1/1677; H10H 29/8517

(57) ABSTRACT

A display device can include a substrate having a first display area in which a plurality of subpixels are disposed and a second display area adjacent to the first display area, a plurality of light-emitting elements disposed in the plurality of subpixels on the substrate, a plurality of color filters disposed in the second display area on the substrate, and a plurality of variable light-blocking layers disposed in the second display area on the plurality of color filters and including a plurality of colored charged particles. Therefore, the plurality of color filters with a high transmittance rate are disposed in the second display area and express a background image, which can implement the display device that expresses the background image while suppressing or addressing a limitation of a decrease in luminance of the display device.

### CROSS-REFERENCE TO RELATED APPLICATIONS

This application claims priority to Korean Patent Application No. 10-2024-0171941, filed on Nov. 27, 2024, in the Korean Intellectual Property Office, the disclosure of which is hereby expressly incorporated by reference into the present application.

### BACKGROUND

### Field

The present disclosure relates to a display device capable of creating an interior effect.

### Discussion of the Related Art

As display devices used for a monitor of a computer, a TV set, a mobile phone, and the like, there are an organic light-emitting display (OLED) configured to autonomously emit, and a liquid crystal display (LCD) that requires a separate light source.

The range of applications of the display devices is diversified from the monitor of the computer and the TV set to personal mobile devices, and studies are being conducted on the display devices having wide display areas and having reduced volumes and weights.

In addition, a display device including a light-emitting diode (LED) has attracted attention as a next-generation display device. Because the LED is made of an inorganic material instead of an organic material, the LED is more reliable and has a longer lifespan than a liquid crystal display device or an organic light-emitting display device. In addition, the LED can be quickly turned on or off, have excellent luminous efficiency, high impact resistance, and great stability, and display high-brightness images.

### SUMMARY OF THE DISCLOSURE

An object to be achieved by the present disclosure is to provide a display device capable of creating an interior effect by disposing a color filter layer in a second display area and allowing the color filter layer to express a background image or pattern.

Another object to be achieved by the present disclosure is to provide a display device capable of suppressing the problem of a decrease in luminance and an increase in power consumption caused by the decrease in luminance in a first display area in which a light-emitting element emits light.

Still another object to be achieved by the present disclosure is to provide a display device capable of easily changing an image visually recognized by a user depending on a light-emitting mode or a non-light-emitting mode of a plurality of light-emitting elements.

Objects of the present disclosure are not limited to the above-mentioned objects, and other objects, which are not mentioned above, can be clearly understood by those skilled in the art from the following descriptions.

A display device according to an embodiment of the present disclosure includes a substrate including a first display area in which a plurality of subpixels are disposed, and a second display area adjacent to the first display area, a plurality of light-emitting elements disposed in the plurality of subpixels on the substrate, a plurality of color filters disposed in the second display area on the substrate, and a plurality of variable light-blocking layers disposed in the second display area on the plurality of color filters and including a plurality of colored charged particles.

A display device according to another embodiment of the present disclosure includes a substrate including a plurality of pixel areas disposed to be spaced apart from one another, and a plurality of opening areas disposed between the plurality of pixel areas, a plurality of pixels disposed in the plurality of pixel areas and each including a plurality of subpixels, a plurality of color filters disposed in the plurality of opening areas on the substrate, and a plurality of variable light-blocking layers disposed in the opening areas on the plurality of color filters and including a plurality of colored charged particles, in which positions of the plurality of colored charged particles move in accordance with a light-emitting mode or a non-light-emitting mode of a plurality of light-emitting elements.

Other detailed matters of the example embodiments of the present disclosure are included in the detailed description and the drawings.

According to aspects of the present disclosure, the color filter layer is disposed in the second display area, and the color filter layer is visually recognized as a background image or pattern by the user, such that the interior effect can be created.

According to aspects of the present disclosure, the color filter layer for expressing a background image or pattern is not disposed in the first display area in which the light-emitting element emits light, which can suppress a problem of a decrease in luminance and an increase in power consumption caused by the decrease in luminance.

According to aspects of the present disclosure, the plurality of light-emitting elements and the plurality of variable light-blocking layers are configured to operate in conjunction with one another, such that the images visually recognized by the user can be easily changed depending on the light-emitting mode or the non-light-emitting mode of the plurality of light-emitting elements.

The effects according to the present disclosure are not limited to the contents exemplified above, and various effects are included in the present disclosure.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a schematic configuration view of a display device according to an embodiment of the present disclosure;

FIG. 2 is a circuit diagram of a subpixel according to the embodiment of the present disclosure;

FIG. 3 is a schematic top plan view illustrating a non-light-emitting mode of a pixel according to the embodiment of the present disclosure;

FIG. 4 is a cross-sectional view taken along line IV-IV′ in FIG. 3;

FIG. 5 is a schematic top plan view illustrating a light-emitting mode of the pixel according to the embodiment of the present disclosure;

FIG. 6 is a cross-sectional view taken along line VI-VI′ in FIG. 5; and

FIG. 7 is a cross-sectional view of a display device according to another embodiment of the present disclosure.

### DETAILED DESCRIPTION OF THE EMBODIMENTS

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the disclosure. Further, in the following description of the present disclosure, a detailed explanation of known related technologies can be omitted to avoid unnecessarily obscuring the subject matter of the present disclosure. The terms such as “including,” “having,” and “comprising” used herein are generally intended to allow other components to be added unless the terms are used with the term “only”. Any references to singular can include plural unless expressly stated otherwise.

Components are interpreted to include an ordinary error range even if not expressly stated.

When the position relation between two parts is described using the terms such as “on”, “above”, “below”, and “next”, one or more parts can be positioned between the two parts unless the terms are used with the term “immediately” or “directly”. Further, the term “can” fully encompasses all the meanings and coverages of the term “may” and vice versa.

When an element or layer is disposed “on” another element or layer, another layer or another element can be interposed therebetween, or it can be directly on the another element or layer.

Although the terms “first”, “second”, and the like are used for describing various components, these components are not confined by these terms. These terms are merely used for distinguishing one component from the other components. Therefore, a first component to be mentioned below can be a second component in a technical concept of the present disclosure.

Same reference numerals generally denote same elements throughout the disclosure.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, various example embodiments of the present disclosure will be described in detail with reference to the accompanying drawings. All the components of each display device/apparatus according to all embodiments of the present disclosure are operatively coupled and configured.

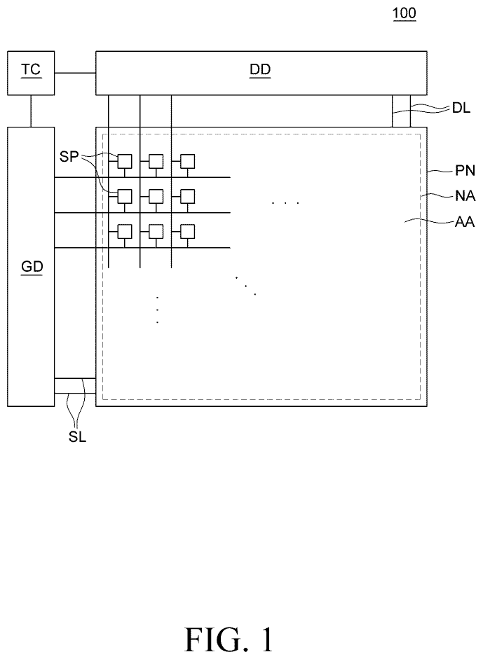

FIG. 1 is a schematic configuration view of a display device according to an embodiment of the present disclosure. For convenience of description, FIG. 1 illustrates a display panel PN, a gate driver GD, a data driver DD, and a timing controller TC among various constituent elements of a display device 100.

With reference to FIG. 1, the display device 100 includes the display panel PN including a plurality of subpixels SP, the gate driver GD configured to supply various types of signals to the display panel PN, and the timing controller TC configured to control the gate driver GD, and the data driver DD.

The gate driver GD supplies a plurality of scan signals to a plurality of scan lines SL in response to a plurality of gate control signals provided from the timing controller TC. FIG. 1 illustrates that the single gate driver GD is disposed to be spaced apart from one side of the display panel PN. However, the number and arrangement of the gate driver GD are not limited thereto.

The data driver DD supplies data voltages to a plurality of data lines DL in response to a plurality of data control signals and image data provided from the timing controller TC. The data driver DD can convert image data into data voltages by using a reference gamma voltage and supply the converted data voltages to the plurality of data lines DL.

The timing controller TC aligns image data, which is inputted from the outside, and supplies the image data to the data driver DD. The timing controller TC can generate the gate control signals and the data control signals by using synchronizing signals, i.e., dot clock signals, data enable signals, and horizontal/vertical synchronizing signals input from the outside. Further, the timing controller TC can control the gate driver GD and the data driver DD by supplying the generated gate control signals and data control signals to the gate driver GD and the data driver DD.

The display panel PN is configured to display images to a user and includes the plurality of subpixels SP. In the display panel PN, the plurality of scan lines SL and the plurality of data lines DL can intersect one another, and the plurality of subpixels SP can be formed at intersection points between the scan line SL and the data line DL.

A display area (or active area) AA and a non-display area (or non-active area) NA can be defined on the display panel PN.

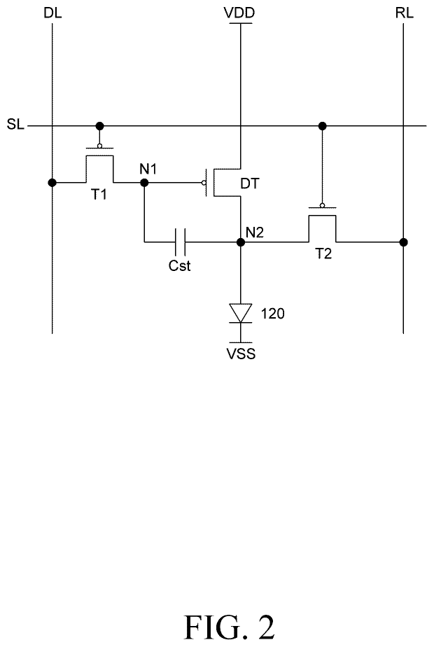

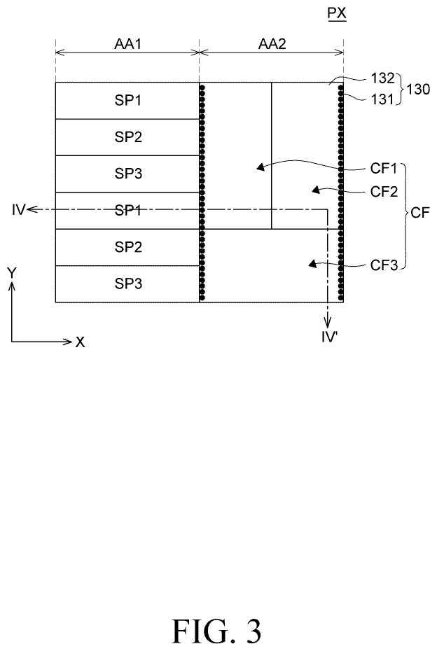

The display area AA is an area of the display device 100 in which images are displayed. The display area AA can include the plurality of subpixels SP constituting a plurality of pixels PX (see FIG. 3), and a subpixel circuit configured to operate the plurality of subpixels SP. The plurality of subpixels SP are minimum units that constitute the display area AA. The n subpixels SP can constitute one pixel PX. Thin-film transistors and the like for operating a plurality of light-emitting elements 120 (see FIG. 2) can be respectively disposed in the plurality of subpixels SP. The plurality of light emitting elements 120 can be differently defined depending on the type of display panel PN. For example, in case that the display panel PN is an inorganic light-emitting display panel, the light-emitting element 120 can be a light-emitting diode (LED) or a micro light-emitting diode (micro LED).

A plurality of signal lines for transmitting various types of signals to the plurality of subpixels SP are disposed in the display area AA. For example, the plurality of signal lines can include the plurality of data lines DL for supplying data voltages to the plurality of subpixels SP, and the plurality of scan lines SL for supplying scan signals to the plurality of subpixels SP. The plurality of scan lines SL can extend in one direction in the display area AA and be connected to the plurality of subpixels SP. The plurality of data lines DL can extend in a direction different from the one direction in the display area AA and be connected to the plurality of subpixels SP. In addition, a low-potential power line, a high-potential power line, and the like can be further disposed in the display area AA. However, the present disclosure is not limited thereto.

The non-display area NA can be defined as an area in which no image is displayed, i.e., an area extending from the display area AA. The non-display area NA can include link lines and pad electrodes for transmitting signals to the subpixels SP in the display area AA. Alternatively, the non-display area NA can include drive ICs such as gate driver ICs and data driver ICs.

Meanwhile, the drivers such as the gate driver GD, the data driver DD, and the timing controller TC can be connected to the display panel PN in various ways. For example, the gate driver GD can be mounted in a non-display area NA by a gate-in-panel (GIP) method or mounted between the plurality of subpixels SP by a gate-in-active area (GIA) method in a display area AA.

FIG. 2 is a circuit diagram of the subpixel according to the embodiment of the present disclosure.

With reference to FIG. 2, the subpixel circuit of each of the plurality of subpixels SP includes a driving transistor DT, a first transistor T1, a second transistor T2, a storage capacitor Cst, and a light-emitting element 120.

The driving transistor DT can include an active layer, a gate electrode, a source electrode, and a drain electrode. The gate electrode is connected to a first node N1, the source electrode is connected to a second node N2, and the drain electrode is connected to a high-potential power line VDD. The driving transistor DT controls a drive current to be supplied to the light-emitting element 120 in response to a gate-source voltage.

The first transistor T1 includes a first active layer, a first gate electrode, a first source electrode, and a first drain electrode. The first gate electrode is connected to the scan line SL, the first source electrode is connected to the first node N1, and the first drain electrode is connected to the data line DL. The first transistor T1 can be turned on or off on the basis of a scan signal from the scan line SL. In case that the first transistor T1 is turned on, the first node N1 can be charged with a data voltage from the data line DL. The first transistor T1 can be referred to as a switching transistor.

The second transistor T2 includes a second active layer, a second gate electrode, a second source electrode, and a second drain electrode. The second gate electrode is connected to the scan line SL, the second source electrode is connected to the second node N2, and the second drain electrode is connected to a reference line RL. The second transistor T2 can be turned on or off on the basis of a sensing signal from the scan line SL. In case that the second transistor T2 is turned on, a reference voltage can be transmitted from the reference line RL to the storage capacitor Cst. The second transistor T2 can be referred to as a sensing transistor.

The storage capacitor Cst includes a plurality of capacitor electrodes. Among the plurality of capacitor electrodes, one capacitor electrode is electrically connected to the second node N2, and the remaining capacitor electrode is electrically connected to the first node N1. The storage capacitor Cst can maintain a potential difference between the gate electrode and the source electrode of the driving transistor DT while the light-emitting element 120 emits light, such that a constant drive current can be supplied to the light-emitting element 120.

The anode of the light-emitting element 120 is connected to the second node N2, and the cathode is connected to a low-potential power line VSS. The light-emitting element 120 can emit light by receiving the drive current from the driving transistor DT.

Meanwhile, FIG. 2 illustrates that the subpixel circuit of the subpixel SP of the display device 100 according to the embodiment of the present disclosure has a 3T1C structure including the three transistors and the single storage capacitor Cst. However, the number of transistors, the number of storage capacitors Cst, and a connection relationship between the transistor and the storage capacitor can be variously changed in accordance with design. The present disclosure is not limited thereto.

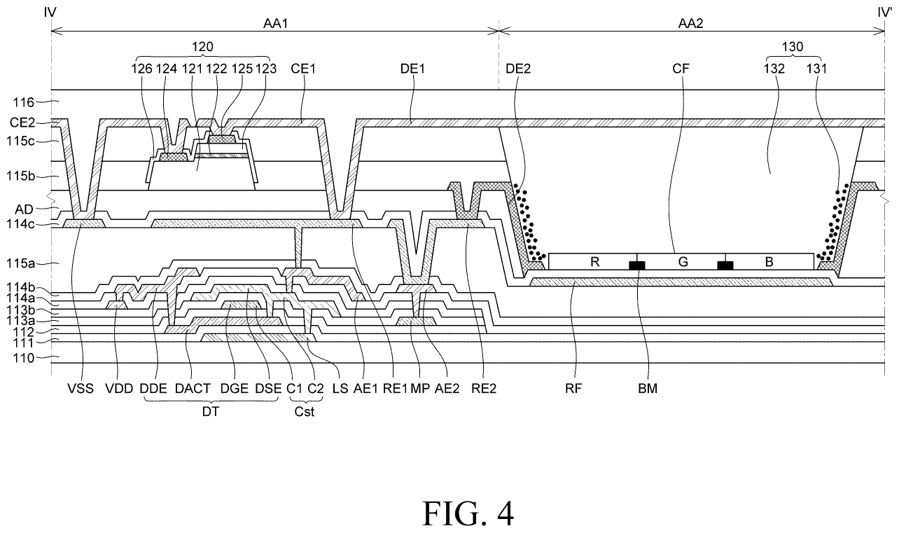

Hereinafter, the display panel PN of the display device 100 according to the embodiment of the present disclosure will be more specifically described with reference to FIGS. 3 and 4.

FIG. 3 is a schematic top plan view illustrating a non-light-emitting mode of the pixel according to the embodiment of the present disclosure. FIG. 4 is a cross-sectional view taken along line IV-IV′ in FIG. 3. For convenience of description, FIG. 3 illustrates only the plurality of subpixels including a first subpixel SP1, a second subpixel SP2, and a third subpixel SP3, a color filter layer CF, and a plurality of variable light-blocking layers 130 among the constituent elements of the pixel PX.

With reference to FIG. 3, the plurality of pixels PX according to the embodiment of the present disclosure each include a first display area (or pixel area) AA1 in which the plurality of subpixels is disposed, and a second display area (or opening area) AA2 adjacent to the first display area AA1.

The first display area AA1 is an area in which the plurality of subpixels is disposed. The first display area AA1 can be referred to as a pixel area. The subpixel circuit, which includes the driving element, and the light-emitting element 120, which is operated by the subpixel circuit, are provided in each of the plurality of subpixels in the first display area AA1, such that the first display area AA1 having the plurality of pixels can be a substantially opaque area. In this case, because the first display area AA1, which is defined as having the plurality of subpixels, is an area in which the light is emitted from the light-emitting element 120, the first display area AA1 can also be defined as a light-emitting area. In addition, because the first display area AA1, which is defined as having the plurality of subpixels, is an area in which the subpixel circuit including the driving element is formed, the first display area AA1 can be defined as a circuit area.

The plurality of first display areas AA1 are areas in which the driving elements and the light-emitting elements 120 are disposed to display images. The plurality of first display areas AA1 can be disposed to be spaced apart from one another with the plurality of second display areas AA2 interposed therebetween.

The plurality of subpixels, in which the plurality of first display areas AA1 are disposed, can each include the light-emitting element 120 and the subpixel circuit and independently emit light. For example, the plurality of subpixels can include the first subpixels SP1, the second subpixels SP2, and the third subpixels SP3 that emit light beams with different colors. For example, the first subpixel SP1 can be a red subpixel, the second subpixel SP2 can be a green subpixel, and the third subpixel SP3 can be a blue subpixel. However, the present disclosure is not limited thereto.

One pixel PX can include the first subpixels SP1, the second subpixels SP2, and the third subpixels SP3 that are sequentially repeated. For example, one pixel PX can include two first subpixels SP1, two second subpixels SP2, and two third subpixels SP3, i.e., two red subpixels, two green subpixels, and two blue subpixels. However, the configuration of the pixel PX is not limited thereto. For example, one pixel PX can include one first subpixel SP1, one second subpixel SP2, and one third subpixel SP3, and the plurality of adjacent pixels PX can share the second display area AA2.

With reference to FIG. 3, the first subpixel SP1, the second subpixel SP2, and the third subpixel SP3 disposed in one first display area AA1 can each have a rectangular shape. For example, the first subpixel SP1, the second subpixel SP2, and the third subpixel SP3 can each have a rectangular shape in which a first length in an X-axis direction can be longer than a second length in a Y-axis direction. However, the present disclosure is not limited thereto. The first subpixel SP1, the second subpixel SP2, and the third subpixel SP3 can each have a rectangular shape in which the first length in the X-axis direction can be shorter than the second length in the Y-axis direction. In addition, the first subpixel SP1, the second subpixel SP2, and the third subpixel SP3 can be identical in shape to one another. However, the present disclosure is not limited thereto. The first subpixel SP1, the second subpixel SP2, and the third subpixel SP3 can be different in shape from one another. Because the first subpixel SP1, the second subpixel SP2, and the third subpixel SP3 can each have a rectangular shape, one first display area AA1 can have a rectangular shape.

The plurality of second display areas AA2 are areas in which images implemented by the color filter layer CF are visually recognized in the display area AA.

In the display device 100 according to the embodiment of the present disclosure, the color filter layer CF can include a first color filter CF1, a second color filter CF2, and a third color filter CF3. For example, the first color filter CF1 can be a red color filter, the second color filter CF2 can be a green color filter, and the third color filter CF3 can be a blue color filter. However, the present disclosure is not limited thereto. In the display device 100 according to the embodiment of the present disclosure, sizes and ratios of the first color filter CF1, the second color filter CF2, and the third color filter CF3 can be adjusted depending on image to be implemented.

The plurality of second display areas AA2 can be disposed to be spaced apart from one another with the plurality of first display areas AA1 interposed therebetween. The plurality of second display areas AA2 can be disposed to surround the plurality of first display areas AA1.

With reference to FIG. 4, a substrate 110 can be configured to support various constituent elements included in the display device 100, and the substrate 110 can be made of an insulating material. For example, the substrate 110 can be made of glass, resin, or the like. In addition, the substrate 110 can include plastic such as polymer and can be made of a material having flexibility.

A light-blocking layer LS is disposed on each of the plurality of subpixels on the substrate 110. The light-blocking layer LS blocks light entering an active layer DACT of the driving transistor DT, which will be described below, from a lower side of the substrate 110. The light-blocking layer LS can block light entering the active layer DACT of the driving transistor DT, thereby minimizing a leakage current.

A buffer layer 111 is disposed on the substrate 110 and the light-blocking layer LS. The buffer layer 111 can reduce the permeation of moisture or impurities through the substrate 110. For example, the buffer layer 111 can be configured as a single layer or multilayer made of silicon oxide (SiOx) or silicon nitride (SiNx). However, the present disclosure is not limited thereto. However, the buffer layer 111 can be excluded in accordance with the type of substrate 110 or the type of transistor. However, the present disclosure is not limited thereto.

The driving transistor DT of each of the plurality of subpixels is disposed on the buffer layer 111. The driving transistor DT is a transistor for controlling a drive current to be supplied to the light-emitting element 120. For convenience of description, FIG. 4 illustrates only the driving transistor DT. However, the first transistor T1 and the second transistor T2 can also be disposed on the buffer layer.

The driving transistor DT includes the active layer DACT, a gate electrode DGE, a source electrode DSE, and a drain electrode DDE.

The active layer DACT is disposed on the buffer layer 111. The active layer DACT can be made of a semiconductor material such as an oxide semiconductor, amorphous silicon, or polysilicon. However, the present disclosure is not limited thereto.

A gate insulation layer 112 is disposed on the active layer DACT. The gate insulation layer 112 is an insulation layer for insulating the active layer DACT and the gate electrode DGE. The gate insulation layer 112 can be configured as a single layer or multilayer made of silicon oxide (SiOx) or silicon nitride (SiNx). However, the present disclosure is not limited thereto.

The gate electrode DGE is disposed on the gate insulation layer 112. The gate electrode DGE can be configured as a single layer or multilayer made of an electrically conductive material, for example, copper (Cu), aluminum (Al), molybdenum (Mo), nickel (Ni), titanium (Ti), chromium (Cr), or an alloy thereof. However, the present disclosure is not limited thereto.

A first capacitor electrode C1 is disposed on the gate insulation layer 112. The first capacitor electrode C1 can be integrated with the gate electrode DGE. The first capacitor electrode C1 can be configured as a single layer or multilayer made of an electrically conductive material, for example, copper (Cu), aluminum (Al), molybdenum (Mo), nickel (Ni), titanium (Ti), chromium (Cr), or an alloy thereof. However, the present disclosure is not limited thereto.

A metal pattern MP is disposed on the gate insulation layer 112. The metal pattern MP can be electrically connected to the gate electrode DGE and disposed on the same layer as the gate electrode DGE. The metal pattern MP can be configured as a single layer or multilayer made of an electrically conductive material, for example, copper (Cu), aluminum (Al), molybdenum (Mo), nickel (Ni), titanium (Ti), chromium (Cr), or an alloy thereof. However, the present disclosure is not limited thereto.

A first interlayer insulation layer 113a is disposed on the gate electrode DGE, the first capacitor electrode C1, and the metal pattern MP. A contact hole, through which the source electrode DSE is connected to the active layer DACT, is formed in the first interlayer insulation layer 113a. The first interlayer insulation layer 113a is an insulation layer for protecting components disposed below the first interlayer insulation layer 113a. The first interlayer insulation layer 113a can be configured as a single layer or multilayer made of silicon oxide (SiOx) or silicon nitride (SiNx). However, the present disclosure is not limited thereto.

The source electrode DSE is disposed on the first interlayer insulation layer 113a. The source electrode DSE is electrically connected to the active layer DACT through a contact hole formed in the first interlayer insulation layer 113a. The source electrode DSE can be configured as a single layer or multilayer made of an electrically conductive material, for example, copper (Cu), aluminum (Al), molybdenum (Mo), nickel (Ni), titanium (Ti), chromium (Cr), or an alloy thereof. However, the present disclosure is not limited thereto.

A second capacitor electrode C2 is disposed on the first interlayer insulation layer 113a. The first capacitor electrode C1 and the second capacitor electrode C2 can be disposed to overlap each other with the first interlayer insulation layer 113a interposed therebetween. The second capacitor electrode C2 can be integrated with the source electrode DSE. The second capacitor electrode C2 can be configured as a single layer or multilayer made of an electrically conductive material, for example, copper (Cu), aluminum (Al), molybdenum (Mo), nickel (Ni), titanium (Ti), chromium (Cr), or an alloy thereof. However, the present disclosure is not limited thereto.

A second interlayer insulation layer 113b is disposed on the source electrode DSE and the second capacitor electrode C2. The second interlayer insulation layer 113b is an insulation layer for protecting components disposed below the second interlayer insulation layer 113b. The second interlayer insulation layer 113b can be configured as a single layer or multilayer made of silicon oxide (SiOx) or silicon nitride (SiNx). However, the present disclosure is not limited thereto.

The high-potential power line VDD is disposed on the second interlayer insulation layer 113b. The high-potential power line VDD can be electrically connected to the drain electrode DDE. The high-potential power line VDD can be configured as a single layer or multilayer made of an electrically conductive material, for example, copper (Cu), aluminum (Al), molybdenum (Mo), nickel (Ni), titanium (Ti), chromium (Cr), or an alloy thereof. However, the present disclosure is not limited thereto.

A first passivation layer 114a is disposed on the second interlayer insulation layer 113b. The first passivation layer 114a can be an insulation layer for protecting components disposed below the first passivation layer 114a. The first passivation layer 114a can be configured as an organic insulation layer or an inorganic insulation layer. For example, the first passivation layer can be configured as an inorganic insulation layer configured as a single layer or multilayer made of silicon oxide (SiOx) or silicon nitride (SiNx) or an organic insulation layer made of a photoresist or an acrylic-based material. However, the present disclosure is not limited thereto.

The drain electrode DDE is disposed on the first passivation layer 114a. The drain electrode DDE is electrically connected to the active layer DACT through contact holes formed in the first passivation layer 114a, the first interlayer insulation layer 113a, the second interlayer insulation layer 113b and the gate insulation layer 112. Further, the drain electrode DDE can be electrically connected to the high-potential power line VDD through a contact hole formed in the first passivation layer 114a. The drain electrode DDE can be configured as a single layer or multilayer made of an electrically conductive material, for example, copper (Cu), aluminum (Al), molybdenum (Mo), nickel (Ni), titanium (Ti), chromium (Cr), or an alloy thereof. However, the present disclosure is not limited thereto.

A first auxiliary electrode AE1 is disposed on the first passivation layer 114a and can be positioned on the same layer as the drain electrode DDE. The first auxiliary electrode AE1 is an electrode for electrically connecting the source electrode DSE and a first reflective electrode RE1. The source electrode DSE and the first reflective electrode RE1 can be electrically connected to each other through the first auxiliary electrode AE1. The first auxiliary electrode AE1 can be configured as a single layer or multilayer made of an electrically conductive material, for example, copper (Cu), aluminum (Al), molybdenum (Mo), nickel (Ni), titanium (Ti), chromium (Cr), or an alloy thereof. However, the present disclosure is not limited thereto.

A second auxiliary electrode AE2 is disposed on the first passivation layer 114a and can be positioned on the same layer as the drain electrode DDE and the first auxiliary electrode AE1. The second auxiliary electrode AE2 can be electrically connected to the metal pattern MP. The second auxiliary electrode AE2 can be configured as a single layer or multilayer made of an electrically conductive material, for example, copper (Cu), aluminum (Al), molybdenum (Mo), nickel (Ni), titanium (Ti), chromium (Cr), or an alloy thereof. However, the present disclosure is not limited thereto.

Next, a second passivation layer 114b is disposed on the first passivation layer 114a, the driving transistor DT, the storage capacitor Cst, the first auxiliary electrode AE1, and the second auxiliary electrode AE2. The second passivation layer 114b can be an insulation layer for protecting components disposed below the second passivation layer 114b. The second passivation layer 114b can be configured as a single layer or multilayer made of silicon oxide (SiOx) or silicon nitride (SiNx). However, the present disclosure is not limited thereto.

A first planarization layer 115a is disposed on the second passivation layer 114b. The first planarization layer 115a can planarize an upper portion of the substrate 110 on which the plurality of transistors and the storage capacitor Cst are disposed. The first planarization layer 115a can be configured as a single layer or multilayer and made of a photoresist or an acrylic-based organic material, for example. However, the present disclosure is not limited thereto.

Meanwhile, an additional passivation layer can be further disposed on the first planarization layer 115a. For example, the passivation layer, which is configured as a single layer or multilayer made of silicon oxide (SiOx) or silicon nitride (SiNx), can be disposed on the first planarization layer 115a and protect the components disposed below the passivation layer.

Next, the reflective electrode RE1 is disposed on the first planarization layer 115a. The first reflective electrodes RE1 can be respectively disposed in the plurality of subpixels and electrically connect the driving transistors DT and the light-emitting elements 120. At the same time, the first reflective electrodes RE1 can reflect the light, which is emitted from the light-emitting elements 120, to the outside of the display device 100. The first reflective electrode RE1 can be disposed adjacent to the source electrode DSE in each of the plurality of subpixels. The first reflective electrode RE1 can be made of an opaque conductive material, such as titanium (Ti), gold (Au), silver (Ag), copper (Cu), molybdenum (Mo), aluminum (Al), or an alloy thereof with high reflection efficiency, made of a conductive material such as indium tin oxide (ITO), or configured as a layered structure made of the opaque conductive material and/or the conductive material. However, the present disclosure is not limited thereto.

A second reflective electrode RE2 is disposed on the first planarization layer 115a. The second reflective electrode RE2 can be disposed in each of the plurality of subpixels and electrically connected to the second auxiliary electrode AE2. At the same time, the light emitted from the light-emitting element 120 can be reflected to the outside of the display device 100. The second reflective electrode RE2 can be made of an opaque conductive material, such as titanium (Ti), gold (Au), silver (Ag), copper (Cu), molybdenum (Mo), aluminum (Al), or an alloy thereof, made of a conductive material such as indium tin oxide (ITO), or configured as a layered structure made of the opaque conductive material and/or the conductive material. However, the present disclosure is not limited thereto.

The low-potential power line VSS is disposed on the first planarization layer 115a. The low-potential power line VSS can supply a low-potential power voltage to the light-emitting element 120. For example, the low-potential power line VSS can be made of an opaque conductive material, such as titanium (Ti), gold (Au), silver (Ag), copper (Cu), molybdenum (Mo), aluminum (Al), or an alloy thereof, made of a conductive material such as indium tin oxide (ITO), or configured as a layered structure made of the opaque conductive material and/or the conductive material. However, the present disclosure is not limited thereto. Because the low-potential power line VSS is made of a material with high reflection efficiency, the low-potential power line VSS can reflect the light, which is emitted from the light-emitting element 120, to the outside of the display device 100. Therefore, the low-potential power line VSS can also be referred to as a third reflective electrode.

A reflective layer RF can be disposed on the first planarization layer 115a in the second display area AA2. The reflective layer RF can reflect the light, which is emitted from the light-emitting element 120, to the outside of the display device 100. The reflective layer RF can be made of an opaque conductive material, such as titanium (Ti), gold (Au), silver (Ag), copper (Cu), molybdenum (Mo), aluminum (Al), or an alloy thereof with high reflection efficiency, made of a conductive material such as indium tin oxide (ITO), or configured as a layered structure made of the opaque conductive material and/or the conductive material. However, the present disclosure is not limited thereto.

A third passivation layer 114c is disposed on the first reflective electrode RE1, the second reflective electrode RE2, the low-potential power line VSS, and the reflective layer RF. The third passivation layer 114c can be an insulation layer for protecting components disposed below the third passivation layer 114c. The third passivation layer 114c can be configured as a single layer or multilayer made of silicon oxide (SiOx) or silicon nitride (SiNx). However, the present disclosure is not limited thereto. A bonding layer AD is disposed on the third passivation layer 114c. In the first display area AA1, the bonding layer AD can be formed on the front surface of the substrate 110 and fix the light-emitting element 120 disposed on the bonding layer AD. The bonding layer AD can be made of a photocurable bonding material that can be cured by light. For example, the bonding layer AD can be made of any one material selected from adhesive polymer, epoxy resist, UV resin, a polyimide-based material, an acrylate-based material, a urethane-based material, and polydimethylsiloxane (PDMS). However, the present disclosure is not limited thereto.

The plurality of light-emitting elements 120 are provided on the first bonding layer AD in the first display area AA1 and disposed in each of the plurality of subpixels. The light-emitting elements 120 can be elements configured to emit light by the current and include a red light-emitting element configured to emit red light, a green light-emitting element configured to emit green light, and a blue light-emitting element configured to emit blue light. A combination of the light-emitting elements 120 can implement light of various colors including white. For example, the light-emitting element 120 can be a light-emitting diode (LED) or a micro LED. However, the present disclosure is not limited thereto.

The red light-emitting element can be disposed in the first subpixel SP1, the green light-emitting element can be disposed in the second subpixel SP2, and the blue light-emitting element can be disposed in the third subpixel SP3.

The plurality of light-emitting elements 120 each includes a first semiconductor layer 121, a light-emitting layer 122, a second semiconductor layer 123, a first electrode 124, a second electrode 125, and an encapsulation film 126.

The first semiconductor layer 121 is disposed on the bonding layer AD, and the second semiconductor layer 123 is disposed on the first semiconductor layer 121. The first semiconductor layer 121 and the second semiconductor layer 123 can each be a layer formed by doping a particular material with n-type and p-type impurities. For example, the first semiconductor layer 121 and the second semiconductor layer 123 can each be a layer formed by doping a material, such as gallium nitride (GaN), indium aluminum phosphide (InAlP), or gallium arsenide (GaAs) with n-type and p-type impurities. Further, the p-type impurity can be magnesium, zinc (Zn), beryllium (Be), or the like. The n-type impurity can be silicon (Si), germanium, tin (Sn), or the like. However, the present disclosure is not limited thereto.

The light-emitting layer 122 is disposed between the first semiconductor layer 121 and the second semiconductor layer 123. The light-emitting layer 122 can emit light by receiving positive holes and negative electrons from the first semiconductor layer 121 and the second semiconductor layer 123. The light-emitting layer 122 can be configured as a single layer or a multi-quantum well (MQW) structure. For example, the light-emitting layer 122 can be made of indium gallium nitride (InGaN), gallium nitride (GaN), or the like. However, the present disclosure is not limited thereto.

The first electrode 124 is disposed on the first semiconductor layer 121. The first electrode 124 is an electrode for electrically connecting the low-potential power line VSS and the first semiconductor layer 121. In this case, the first semiconductor layer 121 can be a semiconductor layer doped with n-type impurities, and the first electrode 124 can be a cathode. The first electrode 124 can be disposed on a top surface of the first semiconductor layer 121 exposed from the light-emitting layer 122 and the second semiconductor layer 123. The first electrode 124 can be made of an electrically conductive material, for example, a transparent conductive material such as indium tin oxide (ITO) or indium zinc oxide (IZO) or an opaque conductive material such as titanium (Ti), gold (Au), silver (Ag), copper (Cu), or an alloy thereof. However, the present disclosure is not limited thereto.

The second electrode 125 is disposed on the second semiconductor layer 123. The second electrode 125 can be disposed on a top surface of the second semiconductor layer 123. The second electrode 125 is an electrode that electrically connects the driving transistor DT and the second semiconductor layer 123. In this case, the second semiconductor layer 123 can be a semiconductor layer doped with p-type impurities, and the second electrode 125 can be an anode. The second electrode 125 can be made of an electrically conductive material, for example, a transparent conductive material such as indium tin oxide (ITO) or indium zinc oxide (IZO) or an opaque conductive material such as titanium (Ti), gold (Au), silver (Ag), copper (Cu), or an alloy thereof. However, the present disclosure is not limited thereto.

Next, the encapsulation film 126 is disposed to surround the first semiconductor layer 121, the light-emitting layer 122, the second semiconductor layer 123, the first electrode 124, and the second electrode 125. The encapsulation film 126 can be made of an insulating material and protect the first semiconductor layer 121, the light-emitting layer 122, and the second semiconductor layer 123. Further, a contact hole, through which the first electrode 124 and the second electrode 125 are exposed, can be formed in the encapsulation film 126, such that a first connection electrode CE1, a second connection electrode CE2, the first electrode 124, and the second electrode 125 can be electrically connected.

Meanwhile, a part of a side surface of the first semiconductor layer 121 can be exposed from the encapsulation film 126. The light-emitting element 120 manufactured on a wafer can be separated from the wafer and transferred to the display panel PN. However, a part of the encapsulation film 126 can be torn during a process of separating the light-emitting element 120 from the wafer. For example, a part of the encapsulation film 126 adjacent to a lower edge of the first semiconductor layer 121 of the light-emitting element 120 can be torn during the process of separating the light-emitting element 120 from the wafer, such that a part of a lower side surface of the first semiconductor layer 121 can be exposed to the outside. Even though the lower portion of the light-emitting element 120 is exposed from the encapsulation film 126, the first connection electrode CE1 and the second connection electrode CE2 are formed after second and third planarization layers 115b and 115c, which cover the side surface of the first semiconductor layer 121, are formed, thereby reducing a short circuit defect.

Next, the second planarization layer 115b and the third planarization layer 115c are disposed on the bonding layer AD and the light-emitting element 120.

The second planarization layer 115b can partially overlap the side surfaces of the plurality of light-emitting elements 120 and fix and protect the plurality of light-emitting elements 120. The second planarization layer 115b can cover a torn portion of the encapsulation film 126 that protects the side surface of the first semiconductor layer 121 of the light-emitting element 120. Therefore, it is possible to suppress the contact between the connection electrode and the first semiconductor layer 121 and a short circuit defect later.

The third planarization layer 115c is formed to cover upper sides of the second planarization layer 115b and the light-emitting element 120. A contact hole, through which the first electrode 124 and the second electrode 125 of the light-emitting element 120 are exposed, can be formed in the third planarization layer 115c. The first electrode 124 and the second electrode 125 of the light-emitting element 120 can be exposed from the third planarization layer 115c. However, the third planarization layer 115c is partially disposed in an area between the first electrode 124 and the second electrode 125, thereby reducing a short circuit defect. The second planarization layer 115b and the third planarization layer 115c can each be configured as a single layer or multilayer and made of a photoresist or an acrylic-based organic material, for example. However, the present disclosure is not limited thereto.

Meanwhile, the color filter layer CF can be disposed on the third passivation layer 114c in the second display area AA2. The color filter layer CF can be disposed to overlap the reflective layer RF. The color filter layer CF can include the first color filter CF1, the second color filter CF2, and the third color filter CF3. The color filter layer CF can express various background images by adjusting ratios or sizes of the first color filter CF1, the second color filter CF2, and the third color filter CF3.

A black matrix BM can be disposed between the first color filter CF1, the second color filter CF2, and the third color filter CF3. The black matrix BM can be provided between the first color filter CF1, the second color filter CF2, and the third color filter CF3 and suppress the occurrence of a color mixture between the first color filter CF1, the second color filter CF2, and the third color filter CF3 that are adjacent to one another. For example, the black matrix BM can include a material that absorbs light, for example, a black dye that absorbs all the light beams in a visible wavelength band.

In the display device 100 according to the embodiment of the present disclosure, some of various insulation layers in the second display area AA2 can be removed. For example, the bonding layer AD, the second planarization layer 115b, and the third planarization layer 115c may not be disposed in the second display area AA2. However, the present disclosure is not limited thereto.

Meanwhile, some of the insulation layers are removed from the second display area AA2, such that side surfaces or ends of the bonding layer AD, the second planarization layer 115b, and the third planarization layer 115c can be exposed in the second display area AA2.

In the second display area AA2, a second driving electrode DE2 is disposed to cover a part of a top surface and the exposed side surface or end of the bonding layer AD. The second driving electrode DE2 can be electrically connected to the second reflective electrode RE2. For example, the second driving electrode DE2 can be made of an opaque conductive material, such as titanium (Ti), gold (Au), silver (Ag), copper (Cu), molybdenum (Mo), aluminum (Al), or an alloy thereof, made of a conductive material such as indium tin oxide (ITO), or configured as a layered structure made of the opaque conductive material and/or the conductive material. However, the present disclosure is not limited thereto.

In the second display area AA2, the variable light-blocking layer 130 including a plurality of colored charged particles 131 can be disposed in a space of an upper portion of the color filter layer CF where the bonding layer AD, the second planarization layer 115b, and the third planarization layer 115c are not disposed.

For example, the variable light-blocking layer 130 can include the plurality of colored charged particles 131 provided in a solvent 132. Specifically, the plurality of colored charged particles 131 can be electrified as negative electric charges or positive electric charges, distributed in the solvent 132, and configured to block the light entering from the outside. For example, the solvent 132 can be a transparent organic solvent. In addition, for example, the plurality of colored charged particles 131 can be electrophoresis materials, for example, made of a material including carbon black. However, the present disclosure is not limited thereto.

The first connection electrode CE1, the second connection electrode CE2, and a first driving electrode DE1 are disposed on the third planarization layer 115c and the variable light-blocking layer 130.

The first connection electrode CE1 is an electrode that electrically connects the driving transistor DT and the second electrode 125 of the light-emitting element 120. The first connection electrode CE1 can be electrically connected to the second electrode 125, which is exposed from the third planarization layer 115c, and simultaneously electrically connected to the first reflective electrode RE1 through contact holes formed in the third planarization layer 115c, the second planarization layer 115b, and the third passivation layer 114c. Therefore, the second electrode 125 and the source electrode DSE can be electrically connected through the first connection electrode CE1, the first reflective electrode RE1, and the auxiliary electrode AE.

The second connection electrode CE2 is an electrode that electrically connects the low-potential power line VSS and the first electrode 124 of the light-emitting element 120. The second connection electrode CE2 can be electrically connected to the first electrode 124, which is exposed from the third planarization layer 115c, and electrically connected to the low-potential power line VSS through contact holes formed in the third planarization layer 115c, the second planarization layer 115b, and the third passivation layer 114c. Therefore, the first electrode 125 and the low-potential power line VSS can be electrically connected through the second connection electrode CE2.

The first driving electrode DE1 can be integrated with the first connection electrode CE1. The first driving electrode DE1 can extend from the first display area AA1 to the second display area AA2 and be disposed to cover the variable light-blocking layer 130 in the second display area AA2.

The first connection electrode CE1, the second connection electrode CE2, and the first driving electrode DE1 can each be made of a transparent conductive material such as indium tin oxide (ITO) or indium zinc oxide (IZO). However, the present disclosure is not limited thereto. Meanwhile, the drawings illustrate that the source electrode DSE of the driving transistor DT and the second electrode 125 of the light-emitting element 120 are electrically connected. However, the drain electrode DDE of the driving transistor DT and the first electrode 124 of the light-emitting element 120 can be electrically connected in accordance with the type of the driving transistor DT and the design of the subpixel circuit. However, the present disclosure is not limited thereto.

Next, a bank can be further disposed on the third planarization layer 115c, the first connection electrode CE1, and the second connection electrode CE2 in the first display area AA1. The bank can be disposed to be spaced apart from the light-emitting element 120 at a predetermined interval. The bank can be disposed on a boundary between the plurality of subpixels and partially cover the first connection electrode CE1 and the second connection electrode CE2. The bank may not be disposed in the second display area AA2. The bank can be made of an opaque material, for example, black resin to reduce a color mixture between the plurality of subpixels. However, the present disclosure is not limited thereto.

A protective layer 116 is disposed on the first connection electrode CE1, the second connection electrode CE2, and the first driving electrode DE1. The protective layer 116 is a layer for protecting components disposed below the protective layer 116. The protective layer 116 can be configured as a single layer or multilayer made of benzocyclobutene, light transmissive epoxy, a photoresist, an acrylic-based organic material, or an inorganic material such as silicon oxide (SiOx) or silicon nitride (SiNx), for example. However, the present disclosure is not limited thereto.

In the display device 100 according to the embodiment of the present disclosure, in a non-light-emitting mode of the plurality of light-emitting elements 120, a background image implemented by the color filter layer CF in the second display area AA2 can be visually recognized by the user.

Specifically, in the display device 100 according to the embodiment of the present disclosure, the plurality of light-emitting elements 120 and the plurality of variable light-blocking layers 130 can be configured to operate in conjunction with one another.

With reference to FIGS. 2 to 4, in the non-light-emitting mode of the plurality of light-emitting elements, i.e., in a time section in which the driving transistor DT is reset among the time sections in which the plurality of light-emitting elements 120 do not emit light, the first transistor T1 and the second transistor T2 are turned on. In this case, a relatively high voltage is applied to the data line DL, and a relatively low voltage is applied to the reference line RL. In this case, a data voltage, which is a high voltage, is applied to the gate electrode DGE of the driving transistor DT and the metal pattern MP. When a high voltage is applied to the metal pattern MP, the high voltage flows along the second auxiliary electrode AE2, which is electrically connected to the metal pattern MP, and the second reflective electrode RE2, which is electrically connected to the second auxiliary electrode AE2, and the high voltage is applied to the second driving electrode DE2 electrically connected to the second reflective electrode RE2. In case that the plurality of colored charged particles 131 are electrified as negative electric charges, the plurality of colored charged particles 131 in the variable light-blocking layer 130 can move onto the second driving electrode DE2 when a high voltage is applied to the second driving electrode DE2.

As illustrated in FIG. 4, because the plurality of colored charged particles 131 are positioned on the second driving electrode DE2 disposed on a lateral portion of the color filter layer CF or a lateral portion of the variable light-blocking layer 130 and spaced apart from the color filter layer CF, the plurality of colored charged particles 131 may not be disposed on the upper portion of the color filter layer CF. The plurality of colored charged particles 131 in the plurality of variable light-blocking layers 130 can be disposed on lateral portions of the plurality of color filters and the plurality of color filters can be exposed when the plurality of light-emitting elements 120 do not emit light. Therefore, in the non-light-emitting mode of the plurality of light-emitting elements 120, a background image implemented by the color filter layer CF in the second display area AA2 can be visually recognized by the user.

In this case, the second driving electrode DE2 can be disposed to be spaced apart from the color filter layer CF without overlapping the color filter layer CF so that the background image implemented by the color filter layer CF is easily visually recognized by the user in the non-light-emitting mode of the plurality of light-emitting elements 120. To this end, an interval between the second driving electrode DE2 and the color filter layer CF, a width and angle of the second driving electrode DE2, and the like can be adjusted.

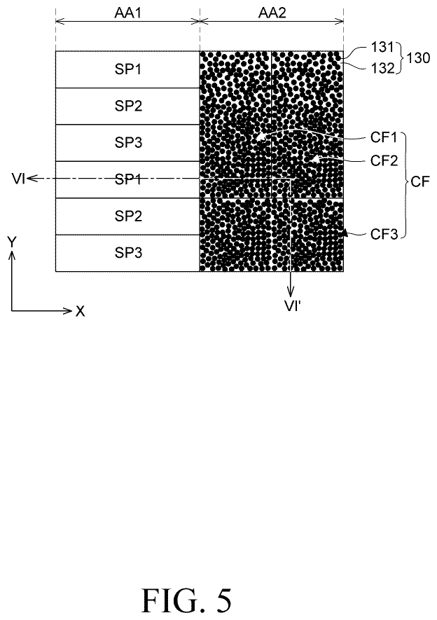

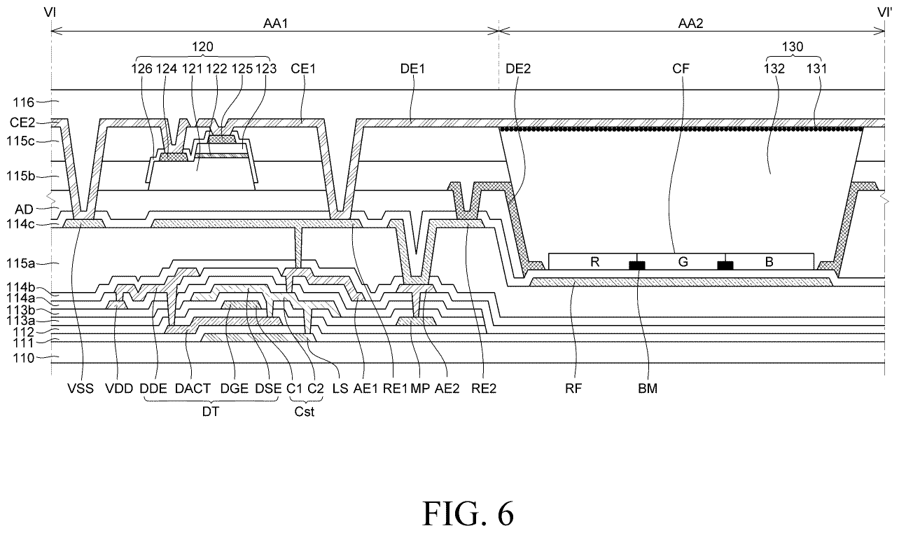

Hereinafter, the light-emitting mode of the plurality of light-emitting elements 120 will be more specifically described with reference to FIGS. 5 and 6 together.

FIG. 5 is a schematic top plan view illustrating the light-emitting mode of the pixel according to the embodiment of the present disclosure. FIG. 6 is a cross-sectional view taken along line VI-VI′ in FIG. 5.

In the display device 100 according to the embodiment of the present disclosure, in the light-emitting mode of the plurality of light-emitting elements 120, an inputted image can be visually recognized by the user.

Specifically, in the display device 100 according to the embodiment of the present disclosure, the plurality of light-emitting elements 120 and the plurality of variable light-blocking layers 130 can be configured to operate in conjunction with one another.

In the display device 100 according to the embodiment of the present disclosure, the plurality of variable light-blocking layers 130 can be operated by the plurality of first driving electrodes DE1. The plurality of colored charged particles131 in the plurality of variable light-blocking layers 130 can be disposed on the plurality of color filters and cover the plurality of color filters when the plurality of light-emitting elements 120 emit light.

Specifically, the plurality of first driving electrodes DE1 can be electrically connected to the plurality of light-emitting elements 120. For example, the plurality of first driving electrodes DE1 can be electrically connected to the first reflective electrode RE1 and extend to the second display area AA2. In this case, the plurality of first driving electrodes DE1 can be disposed on the plurality of variable light-blocking layers 130 in the second display area AA2.

With reference to FIGS. 2, 5, and 6 together, in the light-emitting mode of the plurality of light-emitting elements 120, the light-emitting element 120 is turned on as the electric current flows to the anode, i.e., the second electrode 125 of the light-emitting element 120 through the driving transistor DT. When the light-emitting element 120 is turned on, the voltage is applied to the first connection electrode CE1, which is connected to the second electrode 125 of the light-emitting element 120, and the first driving electrode DE1 electrically connected to the first connection electrode CE1 and extending to the second display area AA2.

When the voltage is applied to the first driving electrode DE1, the plurality of colored charged particles 131 in the variable light-blocking layer 130 can move onto the first driving electrode DE1.

As illustrated in FIGS. 5 and 6, in the display device 100 according to the embodiment of the present disclosure, the first driving electrode DE1 can be positioned to extend to the second display area AA2, such that the plurality of colored charged particles 131 can be disposed on the color filter layer CF and cover the color filter layer CF. Therefore, in the light-emitting mode of the plurality of light-emitting elements 120, the second display area AA2 can be visually recognized as a black area. In the light-emitting mode of the plurality of light-emitting elements 120, the inputted image is visually recognized by the user. In this case, because the background is implemented in a black color, the inputted image can be more clearly displayed, and thus the visibility of the display device 100 can be further improved.

A shy tech technology is used in which the background image of the display device is visually recognized in the non-light-emitting mode of the light-emitting element of the display device, and the input image of the display device is implemented in the light-emitting mode of the light-emitting element. In this case, a decoration film is attached to the upper portion of the display device, such that the background image, i.e., the decoration film is visually recognized. However, in case that the decoration film is attached, a decrease in luminance of the display device is caused by a low transmittance rate of the decoration film, which makes it difficult to visually recognize the input image. Therefore, a high-luminance display device is required, which causes a problem of an increase in power consumption.

Therefore, in the display device 100 according to the embodiment of the present disclosure, the color filter layer CF is disposed only in the second display area AA2 instead of attaching the decoration film to the first display area AA1 and the second display area AA2, and no color filter layer is disposed in the first display area AA1. Therefore, in the non-light-emitting mode of the light-emitting element 120, the background image implemented by the color filter layer CF in the second display area AA2 is visually recognized, such that the color filter layer CF can serve as the decoration film. In the light-emitting mode of the light-emitting element 120, with the absence of the decoration film, the input image can be implemented without decreasing the luminance of the display device 100, and the second display area AA2 is expressed as a black area, such that the clear visibility can be implemented. Further, because the problem of a decrease in luminance of the display device 100 is solved, a high-luminance display device does not need to be applied, which can also suppress the problem of an increase in power consumption.

In the display device 100 according to the embodiment of the present disclosure, the plurality of light-emitting elements 120 and the plurality of variable light-blocking layers 130 are configured to operate in conjunction with one another, such that the images visually recognized by the user can be easily changed depending on the light-emitting mode or the non-light-emitting mode of the plurality of light-emitting elements 120. Therefore, it is possible to switch between the light-emitting mode and the non-light-emitting mode in accordance with the operation of the subpixel circuit without adding a separate circuit.

Further, the decoration film, which is generally used, is attached to the upper portion of the display device and used. However, the color filter layer CF of the display device 100 according to the embodiment of the present disclosure is embedded in the display device 100, such that a process of attaching a separate layer can be excluded.

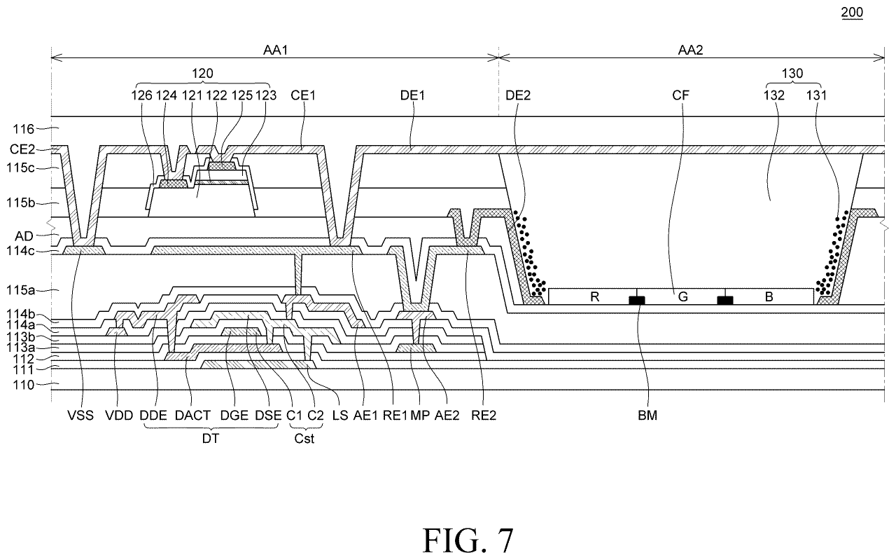

FIG. 7 is a cross-sectional view of a display device according to another embodiment of the present disclosure. A display device 200 in FIG. 7 is substantially identical in configuration to the display device 100 in FIGS. 1 to 6, except that the reflective layer RF is not disposed. Therefore, repeated descriptions of the identical components will be omitted or may be briefly provided.

Referring to FIG. 7, in a display device 200 according to another embodiment of the present disclosure, it is possible to minimize a configuration in which an opaque constituent element is included in the second display area AA2. For example, an opaque metal pattern layer, such as a reflective layer, is not present in the second display area AA2. Therefore, the second display area AA2 has a relatively high transmittance rate, such that the display device can serve as a transparent display device.

In the display device 200 according to another embodiment of the present disclosure, the color filter layer CF is disposed in the second display area AA2, such that the color filter layer CF can be visually recognized as a background image or pattern by the user.

Therefore, in the display device 200 according to another embodiment of the present disclosure, the transmittance rate of the second display area AA2 is ensured, such that the second display area AA2 can be visually recognized as a background image or pattern implemented by the color filter layer CF and the display device 200 can serve as a transparent display device.

The example embodiments of the present disclosure can also be described as follows:
According to an aspect of the present disclosure, a display device includes a substrate including a first display area in which a plurality of subpixels are disposed, and a second display area adjacent to the first display area, a plurality of light-emitting elements disposed in the plurality of subpixels on the substrate, a plurality of color filters disposed in the second display area on the substrate, and a plurality of variable light-blocking layers disposed in the second display area on the plurality of color filters and including a plurality of colored charged particles.

The plurality of light-emitting elements and the plurality of variable light-blocking layers can be configured to operate in conjunction with one another.

The plurality of colored charged particles in the plurality of variable light-blocking layers are disposed on the plurality of color filters and cover the plurality of color filters when the plurality of light-emitting elements emit light, and the plurality of colored charged particles in the plurality of variable light-blocking layers are disposed on lateral portions of the plurality of color filters and the plurality of color filters can be exposed when the plurality of light-emitting elements does not emit light.

The display device can further include a plurality of subpixel circuits disposed in the plurality of subpixels, and a plurality of first driving electrodes and a plurality of second driving electrodes electrically connected to the plurality of subpixel circuits and configured to operate the plurality of variable light-blocking layers.

The plurality of first driving electrodes can be disposed on the plurality of variable light-blocking layers, and the plurality of second driving electrodes can be disposed on lateral portions of the plurality of variable light-blocking layers and spaced apart from the plurality of color filters.

The plurality of subpixel circuits each can include a first transistor having a first source electrode electrically connected to a data line, a driving transistor having a gate electrode electrically connected to the first transistor and having a source electrode electrically connected to the plurality of light-emitting elements, a second transistor having a second source electrode electrically connected to the driving transistor, and a storage capacitor electrically connected to the gate electrode of the driving transistor, the first driving electrode can be electrically connected to the plurality of light-emitting elements, and the second driving electrode can be electrically connected to a metal pattern disposed on the same layer as the gate electrode of the driving transistor.

The display device can further include a first auxiliary electrode positioned on the same layer as a drain electrode of the driving transistor and electrically connected to the source electrode, a planarization layer on the driving transistor, and a first reflective electrode disposed on the planarization layer, the first driving electrode can be electrically connected to the first reflective electrode and can extend to the second display area.

The display device can further include one or more first insulation layers disposed on the metal pattern, a second auxiliary electrode disposed on the one or more first insulation layers, electrically connected to the metal pattern, and positioned on the same layer as the drain electrode of the driving transistor and the first auxiliary electrode, one or more second insulation layers positioned on the second auxiliary electrode, a second reflective electrode positioned on the one or more second insulation layers and electrically connected to the second auxiliary electrode, and one or more third insulation layers positioned on the second reflective electrode, an end of the third insulation layer can be exposed in the second display area, the plurality of second driving electrodes can be disposed to cover the end of the exposed third insulation layer, and the plurality of second driving electrodes can be electrically connected to the second reflective electrode.

In a light-emitting mode of the plurality of light-emitting elements, a voltage is applied to the first driving electrode electrically connected to second electrodes of the plurality of light-emitting elements, and the plurality of colored charged particles in the plurality of variable light-blocking layers can move onto the first driving electrode.

In a non-light-emitting mode of the plurality of light-emitting elements, a voltage is applied to the second driving electrode electrically connected to the metal pattern, and the plurality of colored charged particles in the plurality of variable light-blocking layers can move onto the second driving electrode.

The plurality of color filters can be disposed only in the second display area on the substrate.

According to another aspect of the present disclosure, a display device includes a substrate including a plurality of pixel areas disposed to be spaced apart from one another, and a plurality of opening areas disposed between the plurality of pixel areas, a plurality of pixels disposed in the plurality of pixel areas and each including a plurality of subpixels, a plurality of color filters disposed in the plurality of opening areas on the substrate, and a plurality of variable light-blocking layers disposed in the opening areas on the plurality of color filters and including a plurality of colored charged particles, in which positions of the plurality of colored charged particles move in accordance with a light-emitting mode or a non-light-emitting mode of a plurality of light-emitting elements.

In the light-emitting mode of the plurality of light-emitting elements, the plurality of colored charged particles in the plurality of variable light-blocking layers can be disposed on the plurality of color filters and can cover the plurality of color filters, and in the non-light-emitting mode of the plurality of light-emitting elements, the plurality of colored charged particles in the plurality of variable light-blocking layers can be disposed on lateral portions of the plurality of color filters, and the plurality of color filters can be exposed.

The display device can further include a plurality of subpixel circuits disposed in the plurality of subpixels, and a plurality of first driving electrodes and a plurality of second driving electrodes electrically connected to the plurality of subpixel circuits and configured to operate the plurality of variable light-blocking layers.

The plurality of subpixel circuits each can include a first transistor having a first source electrode electrically connected to a data line, a driving transistor having a gate electrode electrically connected to the first transistor and having a source electrode electrically connected to the plurality of light-emitting elements, a second transistor having a second source electrode electrically connected to the driving transistor, and a storage capacitor electrically connected to the gate electrode of the driving transistor, the first driving electrode can be electrically connected to anode electrodes of the plurality of light-emitting elements, and the second driving electrode can be electrically connected to a metal pattern disposed on the same layer as the gate electrode of the driving transistor.

In the light-emitting mode of the plurality of light-emitting elements, a voltage is applied to a first driving electrode electrically connected to the anode electrodes of the plurality of light-emitting elements, and the plurality of colored charged particles in the plurality of variable light-blocking layers can move onto the first driving electrode.

In the non-light-emitting mode of the plurality of light-emitting elements, a voltage is applied to the second driving electrode electrically connected to the metal pattern, and the plurality of colored charged particles in the plurality of variable light-blocking layers can move onto the second driving electrode.

The plurality of color filters can be disposed only in the plurality of opening areas on the substrate.

Although the example embodiments of the present disclosure have been described in detail with reference to the accompanying drawings, the present disclosure is not limited thereto and can be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device comprising:
a substrate comprising a first display area in which a plurality of subpixels are disposed, and a second display area adjacent to the first display area;
a plurality of light-emitting elements disposed in the plurality of subpixels on the substrate;
a plurality of color filters disposed in the second display area on the substrate; and
a plurality of variable light-blocking layers disposed in the second display area on the plurality of color filters, and comprising a plurality of colored charged particles.

2. The display device of claim 1,
wherein the plurality of light-emitting elements and the plurality of variable light-blocking layers are configured to operate in conjunction with one another.

3. The display device of claim 2,
wherein the plurality of colored charged particles in the plurality of variable light-blocking layers are disposed on the plurality of color filters and cover the plurality of color filters when the plurality of light-emitting elements emit light, and
wherein the plurality of colored charged particles in the plurality of variable light-blocking layers are disposed on lateral portions of the plurality of color filters, and the plurality of color filters are exposed when the plurality of light-emitting elements do not emit light.

4. The display device of claim 3, further comprising:
a plurality of subpixel circuits disposed in the plurality of subpixels; and
a plurality of first driving electrodes and a plurality of second driving electrodes electrically connected to the plurality of subpixel circuits and configured to operate the plurality of variable light-blocking layers.

5. The display device of claim 4,
wherein the plurality of first driving electrodes are disposed on the plurality of variable light-blocking layers, and
wherein the plurality of second driving electrodes are disposed on lateral portions of the plurality of variable light-blocking layers and spaced apart from the plurality of color filters.

6. The display device of claim 5,
wherein each of the plurality of subpixel circuits further comprises:
a first transistor having a first source electrode electrically connected to a data line;
a driving transistor having a gate electrode electrically connected to the first transistor and having a source electrode electrically connected to the plurality of light-emitting elements;
a second transistor having a second source electrode electrically connected to the driving transistor; and
a storage capacitor electrically connected to the gate electrode of the driving transistor,
wherein the first driving electrode is electrically connected to the plurality of light-emitting elements, and
wherein the second driving electrode is electrically connected to a metal pattern disposed on a same layer as the gate electrode of the driving transistor.

7. The display device of claim 6, further comprising:
a first auxiliary electrode positioned on a same layer as a drain electrode of the driving transistor and electrically connected to the source electrode;
a planarization layer on the driving transistor; and
a first reflective electrode disposed on the planarization layer,
wherein the first driving electrode is electrically connected to the first reflective electrode and extends to the second display area.

8. The display device of claim 7, further comprising:
one or more first insulation layers disposed on the metal pattern;
a second auxiliary electrode disposed on the one or more first insulation layers, electrically connected to the metal pattern, and positioned on the same layer as the drain electrode of the driving transistor and the first auxiliary electrode;
one or more second insulation layers positioned on the second auxiliary electrode;
a second reflective electrode positioned on the one or more second insulation layers and electrically connected to the second auxiliary electrode; and
one or more third insulation layers positioned on the second reflective electrode,
wherein an end of the third insulation layer is exposed in the second display area,
wherein the plurality of second driving electrodes are disposed to cover the end of the exposed third insulation layer, and
wherein the plurality of second driving electrodes are electrically connected to the second reflective electrode.

9. The display device of claim 6,
wherein in a light-emitting mode of the plurality of light-emitting elements, a voltage is applied to the first driving electrode electrically connected to second electrodes of the plurality of light-emitting elements, and the plurality of colored charged particles in the plurality of variable light-blocking layers move onto the first driving electrode.

10. The display device of claim 6,
wherein in a non-light-emitting mode of the plurality of light-emitting elements, a voltage is applied to the second driving electrode electrically connected to the metal pattern, and the plurality of colored charged particles in the plurality of variable light-blocking layers move onto the second driving electrode.

11. The display device of claim 1, wherein the plurality of color filters are disposed only in the second display area on the substrate.

12. A display device comprising:
a substrate comprising a plurality of pixel areas disposed to be spaced apart from one another, and a plurality of opening areas disposed between the plurality of pixel areas;
a plurality of pixels disposed in the plurality of pixel areas, each of the plurality of pixels comprising a plurality of subpixels;
a plurality of color filters disposed in the plurality of opening areas on the substrate; and
a plurality of variable light-blocking layers disposed in the plurality of opening areas on the plurality of color filters, the plurality of variable light-blocking layers comprising a plurality of colored charged particles,
wherein positions of the plurality of colored charged particles move in accordance with a light-emitting mode or a non-light-emitting mode of the plurality of light-emitting elements.

13. The display device of claim 12,
wherein in the light-emitting mode of the plurality of light-emitting elements, the plurality of colored charged particles in the plurality of variable light-blocking layers are disposed on the plurality of color filters and cover the plurality of color filters.

14. The display device of claim 13,
wherein in the non-light-emitting mode of the plurality of light-emitting elements, the plurality of colored charged particles in the plurality of variable light-blocking layers are disposed on lateral portions of the plurality of color filters, and the plurality of color filters are exposed.

15. The display device of claim 12, further comprising:
a plurality of subpixel circuits disposed in the plurality of subpixels; and
a plurality of first driving electrodes and a plurality of second driving electrodes electrically connected to the plurality of subpixel circuits and configured to operate the plurality of variable light-blocking layers.

16. The display device of claim 12, wherein each of the plurality of subpixel circuits further comprises:
a first transistor having a first source electrode electrically connected to a data line;
a driving transistor having a gate electrode electrically connected to the first transistor and having a source electrode electrically connected to the plurality of light-emitting elements;
a second transistor having a second source electrode electrically connected to the driving transistor; and
a storage capacitor electrically connected to the gate electrode of the driving transistor.

17. The display device of claim 16,
wherein the first driving electrode is electrically connected to anode electrodes of the plurality of light-emitting elements, and
wherein the second driving electrode is electrically connected to a metal pattern disposed on the same layer as the gate electrode of the driving transistor.

18. The display device of claim 17,
wherein in the light-emitting mode of the plurality of light-emitting elements, a voltage is applied to a first driving electrode electrically connected to the anode electrodes of the plurality of light-emitting elements, and the plurality of colored charged particles in the plurality of variable light-blocking layers move onto the first driving electrode.

19. The display device of claim 17,
wherein in the non-light-emitting mode of the plurality of light-emitting elements, a voltage is applied to the second driving electrode electrically connected to the metal pattern, and the plurality of colored charged particles in the plurality of variable light-blocking layers move onto the second driving electrode.

20. The display device of claim 12,
wherein the plurality of color filters are disposed only in the plurality of opening areas on the substrate.
